(19) United States
(12) Patent Application Publication
(10) Pub. No.: US 2022/0341972 A1
(43) Pub. Date: Oct. 27, 2022

(54) DIAGNOSIS DEVICE, DIAGNOSIS METHOD, AND DIAGNOSIS PROGRAM

(71) Applicant: MITSUBISHI HEAVY INDUSTRIES, LTD., Tokyo (JP)

(72) Inventors: Yohei CHISHIKI, Tokyo (JP); Koki TATEISHI, Tokyo (JP); Takashi SONODA, Tokyo (JP)

(21) Appl. No.: 17/640,504

(22) PCT Filed: Feb. 10, 2020
(86) PCT No.: PCT/JP2020/005202

§ 371 Date: Mar. 4, 2022

(30) Foreign Application Priority Data
Sep. 13, 2019 (JP) 2019-166839

(51) Int. Cl. G01R 19/02; G01R 19/25

(52) U.S. Cl. CPC G01R 19/02; G01R 19/25

(57) ABSTRACT

A diagnosis device for diagnosing a diagnosis target machine having a rotary machine on the basis of a measured current during rotation of the rotary machine is provided with: an effective value acquisition unit configured to acquire an effective value of the measured current for each specified number of cycles in a target current waveform which is time transition of the measured current in a first predetermined period; a distribution information calculation unit configured to calculate a target distribution information which represents a distribution state of a plurality of the effective values acquired; and a detection unit configured to perform abnormality detection of the diagnosis target machine on the basis of the calculated target distribution information.

### TECHNICAL FIELD

The present disclosure relates to a diagnosis technology for a device having a rotary machine.

### BACKGROUND

For example, Patent Documents 1 and 2 disclose a method of detecting an abnormality in a rotary machine such as an electric motor on the basis of a current value of the rotary machine. Specifically, Patent Document 1 discloses that motor abnormality of a fan motor is judged (detected) by comparing an effective value of current flowing through the fan motor with a threshold set according to the power supply frequency and power supply voltage when the effective value is obtained. Further, Patent Document 2 discloses that since the amplitude probability density function of current waveform changes as the facility condition changes, abnormality in the electric motor is detected by calculating the Kullback-Leibler distance (information distance) between a reference amplitude probability density function obtained from a reference sine wave of the rated current of the electric motor and an inspection amplitude probability density obtained from the current waveform measured during operation of the electric motor.

### CITATION LIST

### Patent Literature

Patent Document 1: JP2013-050294A
Patent Document 2: JP2011-257362A

### SUMMARY

### Problems to be Solved

The current value of a motor varies greatly depending on the load and characteristics of the motor. For this reason, when abnormality in the motor is detected by monitoring an effective value with a threshold, it is necessary to set the threshold for each load and motor characteristics, but in practice, it is difficult to set the threshold individually since the number of thresholds is enormous. Similarly, in the method of calculating the degree of abnormality based on the sine wave of the rated current, since the current value varies greatly depending on the load and motor, there is a possibility of judging as abnormal what should actually be judged as normal.

In view of the above, an object of at least one embodiment of the present invention is to provide a diagnosis device with improved accuracy in abnormality detection based on measured current of a device having a rotary machine.

### Solution to the Problems

A diagnosis device according to at least one embodiment of the present invention is a diagnosis device for diagnosing a diagnosis target machine having a rotary machine on the basis of a measured current during rotation of the rotary machine and comprises: an effective value acquisition unit configured to acquire an effective value of the measured current for each specified number of cycles in a target current waveform which is time transition of the measured current in a first predetermined period; a distribution information calculation unit configured to calculate a target distribution information which represents a distribution state of a plurality of the effective values acquired; and a detection unit configured to perform abnormality detection of the diagnosis target machine on the basis of the calculated target distribution information.

Further, a diagnosis method according to at least one embodiment of the present invention is a diagnosis method for diagnosing a diagnosis target machine having a rotary machine on the basis of a measured current during rotation of the rotary machine and comprises: a step of acquiring an effective value of the measured current for each specified number of cycles in a target current waveform which is time transition of the measured current in a first predetermined period; a step of calculating a target distribution information which represents a distribution state of a plurality of the effective values acquired; and a step of performing abnormality detection of the diagnosis target machine on the basis of the calculated target distribution information.

Further, a diagnosis program according to at least one embodiment of the present invention is a diagnosis program for diagnosing a diagnosis target machine having a rotary machine on the basis of a measured current during rotation of the rotary machine and is configured to cause a computer to implement: an effective value acquisition unit configured to acquire an effective value of the measured current for each specified number of cycles in a target current waveform which is time transition of the measured current in a first predetermined period; a distribution information calculation unit configured to calculate a target distribution information which represents a distribution state of a plurality of the effective values acquired; and a detection unit configured to perform abnormality detection of the diagnosis target machine on the basis of the calculated target distribution information.

### Advantageous Effects

At least one embodiment of the present invention provides a diagnosis device with improved accuracy in abnormality detection based on measured current of a device having a rotary machine.

### BRIEF DESCRIPTION OF DRAWINGS

FIG. 1 is a diagram schematically showing a diagnosis system including a diagnosis device and a diagnosis target machine according to an embodiment of the present invention.

FIG. 2 is a diagram schematically showing a function of the diagnosis device according to an embodiment of the present invention.

FIG. 3A is a diagram showing effective values of current for a certain type of abnormality in contrast between normal and abnormal conditions according to an embodiment of the present invention.

FIG. 3B is a diagram showing effective values of current for another type of abnormality in contrast between normal and abnormal conditions according to an embodiment of the present invention.

FIG. 4A is a diagram showing a probability density distribution of effective values when the rotary machine is abnormal according to an embodiment of the present invention.

FIG. 4B is a diagram showing a probability density distribution of effective values when the rotary machine is normal according to an embodiment of the present invention.

FIG. 5 is a diagram showing normal current waveforms of a plurality of diagnosis target machines in contrast to each other according to an embodiment of the present invention.

FIG. 6 is a diagram for describing the flow of diagnosis according to an embodiment of the present invention.

FIG. 7 is a diagram of the diagnosis method according to an embodiment of the present invention.

### DETAILED DESCRIPTION

Embodiments of the present invention will now be described in detail with reference to the accompanying drawings. It is intended, however, that unless particularly identified, dimensions, materials, shapes, relative positions, and the like of components described in the embodiments shall be interpreted as illustrative only and not intended to limit the scope of the present invention.

For instance, an expression of relative or absolute arrangement such as “in a direction”, “along a direction”, “parallel”, “orthogonal”, “centered”, “concentric” and “coaxial” shall not be construed as indicating only the arrangement in a strict literal sense, but also includes a state where the arrangement is relatively displaced by a tolerance, or by an angle or a distance whereby it is possible to achieve the same function.

For instance, an expression of an equal state such as “same” “equal” and “uniform” shall not be construed as indicating only the state in which the feature is strictly equal, but also includes a state in which there is a tolerance or a difference that can still achieve the same function.

Further, for instance, an expression of a shape such as a rectangular shape or a cylindrical shape shall not be construed as only the geometrically strict shape, but also includes a shape with unevenness or chamfered corners within the range in which the same effect can be achieved.

On the other hand, an expression such as “comprise”, “include”, “have”, “contain” and “constitute” are not intended to be exclusive of other components.

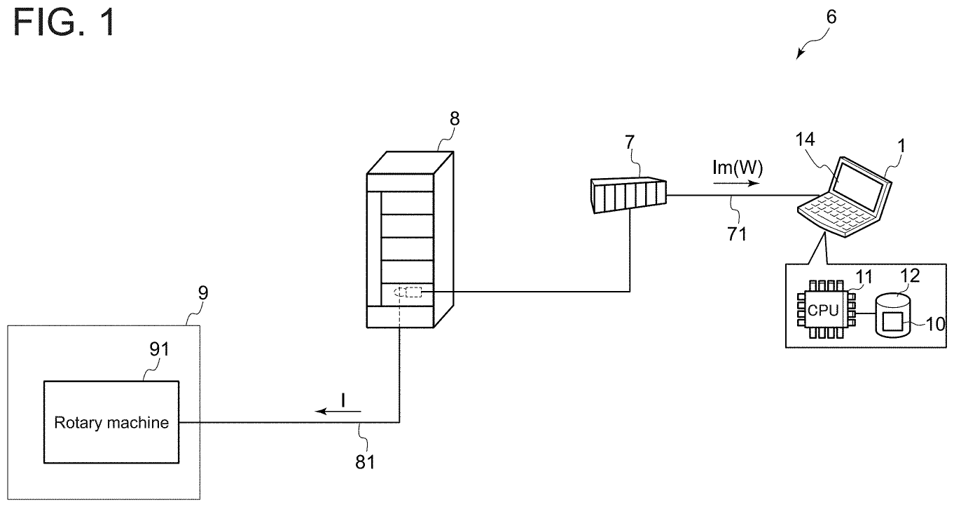

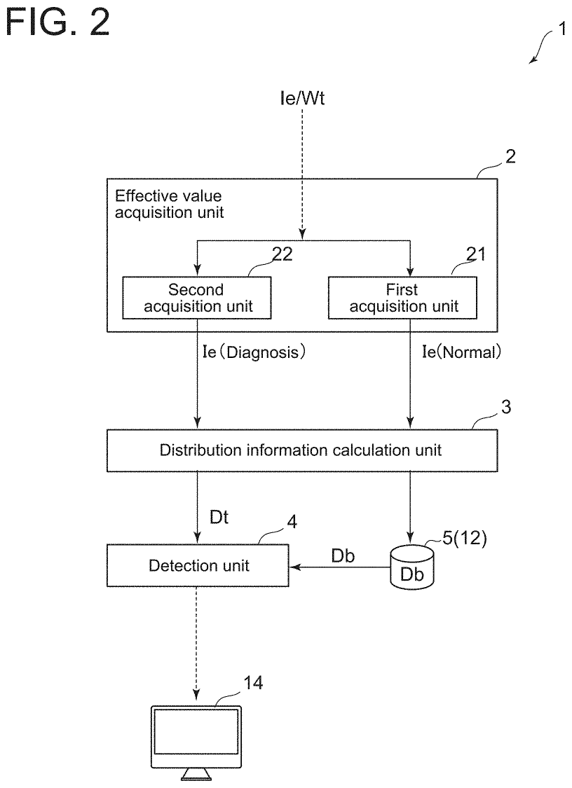

FIG. 1 is a diagram schematically showing a diagnosis system 6 including a diagnosis device 1 and a diagnosis target machine 9 according to an embodiment of the present invention. FIG. 2 is a diagram schematically showing a function of the diagnosis device 1 according to an embodiment of the present invention.

As shown in FIG. 1, the diagnosis device 1 is a device for diagnosing a diagnosis target machine 9 having a rotary machine 91 on the basis of a measured current during rotation of the rotary machine 91. The rotary machine 91 may be, for example, an electric motor such as a motor or a pump which converts supplied electric energy into rotational force, a generator which converts mechanical energy into electric energy by rotating a rotor by the mechanical energy, or a gas turbine or a steam turbine which rotationally drives such a generator. The diagnosis target machine 9 may be, for example, an electric motor or a generator itself having the rotary machine 91 as a main component, a machine (device) such as a vehicle including such an electric motor or a generator, or a power generation device including a steam turbine or a gas turbine with a rotational shaft connected to a drive shaft of a generator to generate electric energy. The power generation device may constitute a power generation plant such as a thermal power generation plant or a gas turbine combined cycle (GTCC) power generation plant.

For example, as shown in FIG. 1, the diagnosis device 1 may be connected to a current measurement device 7 capable of measuring current I in the diagnosis target machine 9, such as alternating current supplied to the rotary machine (electric motor) of the diagnosis target machine 9 or alternating current output from the rotary machine (electric motor), to monitor the current I in real time. In the embodiment shown in FIG. 1, the diagnosis target machine 9 is a machine including an electric motor as the rotary machine 91. An alternating current I flowing through a wiring (power supply line 81) connecting the electric motor and an electric panel 8 such as a switchboard, a distribution board, or a control panel for inputting (supplying) electric power to rotationally drive the electric motor is measured by the current measurement device 7 using a small clamp. Further, the current measurement device 7 transmits (inputs) a measured value Im of the current I (measured current) to the diagnosis device 1 via a communication medium 71 (communication line in FIG. 1) such as wired or wireless.

For example, if the diagnosis target machine 9 includes a generator and a gas turbine or a steam turbine for rotationally driving the generator as the rotary machines 91, the current I output from the generator to the electric panel 8 may be measured as the measured current. In other words, if the diagnosis target machine 9 includes two or more rotary machines 91 that rotate in association with each other, the current I output from one of the rotary machines 91 or the current I input (supplied) to one of the rotary machines 91 may be used as the measured current. For example, by measuring the current I generated by power generation of the steam turbine or the like, it is possible to diagnose whether both the steam turbine and the generator are normal, and it is possible to detect an abnormality if it occurs in at least one of them.

However, the present invention is not limited to the embodiment shown in FIG. 1. In other embodiments, the diagnosis target machine 9 may not be connected to the current measurement device 7. In this case, time transition data of the measured value Im through the measurement by the current measurement device 7 may be stored, and this data may be input to the diagnosis device 1 via a portable storage medium such as a USB memory, an SD memory, or a compact flash (registered trademark). Alternatively, the diagnosis device 1 may be configured to receive the time transition data of the measured value Im via a communication network.

The diagnosis device 1 will now be described with reference to FIG. 2 in detail.

As shown in FIG. 2, the diagnosis device 1 includes an effective value acquisition unit 2, a distribution information calculation unit 3, and a detection unit 4. This diagnosis device 1 is composed of a computer. For example, the diagnosis device 1 may be a laptop computer as shown in FIG. 1. Each functional unit of the diagnosis device 1 will now be described.

The computer includes, for example, a processor 11 such as CPU (not shown), a memory (storage device 12) such as ROM and RAM. The processor 11 performs an operation (such as computation of data) in accordance with an instruction of a program (diagnosis program 10) loaded to a main storage device, thereby implementing each of the functional units. In other words, the diagnosis program 10 is software for causing the computer to implement the functional units, not a temporary signal, and may be stored in a storage medium which is computer-readable and portable as described above.

The effective value acquisition unit 2 is a functional unit configured to acquire an effective value Ie of the measured current for each specified number of cycles in a current waveform W (hereinafter, target current waveform Wt) which is time transition of the measured current of the diagnosis target machine 9 in a predetermined period (hereinafter, first predetermined period). The specified number of cycles is one or more (one or more cycles). The first predetermined period is a period of time including a plurality of current waveforms W of the predetermined number of cycles of the measured current. That is, the target current waveform Wt is formed (configured) by the time transition of the measured current over a plurality of cycles. Thus, by calculating the effective value Ie on the basis of each current waveform W (hereinafter, unit current waveform Wu) of the specified number of cycles arranged along the time axis in the target current waveform Wt, a plurality of effective values Ie is obtained from the target current waveform Wt.

For example, calculation of the plurality of effective values Ie may be performed by the effective value acquisition unit 2. In this case, the measured value Im of the current input from the current measurement device 7 to the diagnosis device 1 is an instantaneous value of the current. The effective value acquisition unit 2 may obtain the entire target current waveform Wt, then identify the plurality of unit current waveforms Wu forming the acquired target current waveform Wt so that there is no overlapping along the time axis, and calculate the effective value Ie of each unit current waveform Wu. Alternatively, the effective value acquisition unit 2 may sequentially obtain each part of the target current waveform Wt according to the passage of time and sequentially calculate the effective value Ie for the obtained unit current waveform.

Alternatively, calculation of the plurality of effective values Ie may be performed by another device such as the above-described current measurement device 7. In this case, the measured value Im of the current input from the current measurement device 7 to the diagnosis device 1 is the effective value Ie. The effective value acquisition unit 2 may perform the following processing when the effective values Ie of the current of the number expected to be obtained in the first predetermined period is obtained.

More specifically, the effective value Ie is calculated on the basis of a plurality of instantaneous values of the current obtained by sampling from each unit current waveform Wu forming the target current waveform Wt. In other words, from one unit current waveform Wu, current instantaneous values at different times are sampled at equal intervals, for example. More specifically, the number of samples by the sampling is preferably 900 to 1200 per cycle of one or more cycles constituting the unit current waveform Wu. This ensures that the processing load is not excessive while achieving the necessary accuracy. In the embodiment shown in FIGS. 1 and 2, the number of samples is in the range of 1070 to 1110, for example 1090. The predetermined number of cycles is one cycle. By setting the number of samples appropriately, the operating state (normal or abnormal) of the rotary machine is appropriately reflected in target distribution information described below.

As already described, the measured current may be obtained by measuring the current of electric power supplied to the diagnosis target machine 9 (rotary machine 91), or may be obtained by measuring the current of electric power output from the diagnosis target machine 9 (rotary machine 91). Further, the target current waveform Wt may be acquired by measuring instantaneous values of the current in real time using the current measurement device 7 for the first predetermined period, or data of the target current waveform Wt already measured may be acquired.

The distribution information calculation unit 3 is a functional unit configured to calculate distribution information (hereinafter, target distribution information Dt) which represents a distribution state of the plurality of the effective values Ie acquired by the effective value acquisition unit 2. This distribution information may be a probability distribution such as a probability density function or may be a shape of the distribution, a standard deviation or a variance value obtained by quantifying the shape of the distribution. In the embodiment shown in FIGS. 1 and 2, the number of effective values Ie to be acquired to generate the target distribution information Dt is 400 or more. Thus, the operating state (normal or abnormal) of the rotary machine can be appropriately reflected in the target distribution information Dt.

The detection unit 4 is a functional unit configured to perform abnormality detection of the diagnosis target machine 9 on the basis of the target distribution information Dt calculated by the distribution information calculation unit 3. This abnormality detection (abnormality detection process) is to determine whether the diagnosis target machine 9 is normal or abnormal, and can determine the occurrence of an abnormality that would affect the effective value Ie of the measured current. For example, it is possible to detect abnormalities such as misalignment, cavitation in the pump that causes bubbles of vaporized liquid due to pressure drop in the pipe, contact with the disk, loosening of the belt, and ground faults.

In the embodiment shown in FIGS. 1 and 2, as shown in FIG. 2, the diagnosis device 1 is connected to the current measurement device 7 so that the measured value Im of the current is input from the current measurement device 7 to the diagnosis device 1 in real time. The effective value acquisition unit 2 acquires this value. Further, in the diagnosis device 1, the effective value acquisition unit 2 and the distribution information calculation unit 3 are connected. The distribution information calculation unit 3 calculates the target distribution information Dt on the basis of the plurality of effective values Ie input from the effective value acquisition unit 2. Further, the detection unit 4, which is connected to the distribution information calculation unit 3, performs the abnormality detection when the target distribution information Dt is input from the distribution information calculation unit 3. Additionally, the detection unit 4 outputs the result of abnormality detection to an output device 14. In this embodiment, the output device 14 is a display device such as a display, but in other embodiments, the output device 14 may be other than the display device as long as it can inform the user of the result of abnormality detection. The output device 14 may include at least one of: a display, a printer, a speaker, or a light-emitting device such as an LED.

When the diagnosis target machine 9 includes a steam turbine and a generator, for example, the steam turbine drives the generator. Due to this relationship, for example, if an abnormality is determined when diagnosis is performed using the time transition of the current generated by the generator as the target current waveform Wt, it is suspected that the abnormality occurs in least one of the steam turbine or the generator. Thus, the diagnosis by the detection unit 4 may be used as the primary diagnosis, and if an abnormality is detected, a detailed investigation may be performed.

According to the above configuration, during rotation of the rotary machine 91 such as a turbine, a generator, or a motor of the diagnosis target machine 9, the effective value Ie of the current waveform W (unit current waveform Wu described below) for each specified number of cycles in the current waveform W (target current waveform Wt), which is the time transition of instantaneous values of the current I (measured current), such as alternating current supplied to the rotary machine 91 (e.g., electric motor) or alternating current output from the rotary machine 91 (e.g., generator), is acquired. Then, on the basis of information (target distribution information Dt) which represents the distribution state, such as probability density function and standard deviation, of the plurality of effective values Ie thus acquired, abnormality detection of the diagnosis target machine 9 is performed.

The present inventors have found that, depending on the type of abnormality in the rotary machine 91, the abnormality determination is more accurate when based on the distribution state of effective values of the current than when based on the distribution state of instantaneous values of the current when the abnormality occurs (see Patent Document 2). Therefore, by executing the diagnosis of the rotary machine 91 on the basis of the distribution state (variation) of the plurality of effective values Ie of the current obtained from the target current waveform Wt, it is possible to appropriately diagnose whether the rotary machine 91 is normal or abnormal.

Next, some embodiments of the detection unit 4 will be described in detail.

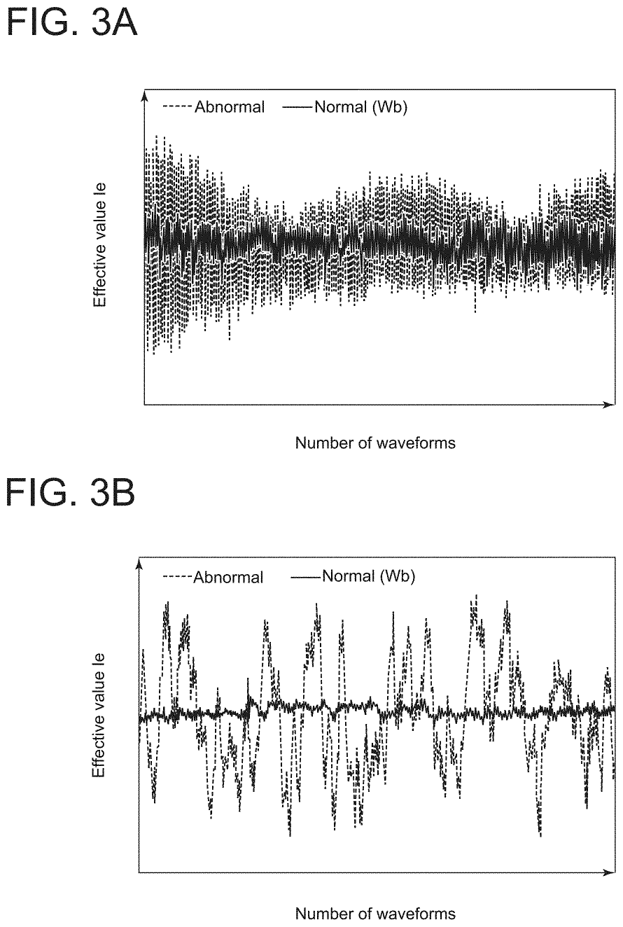

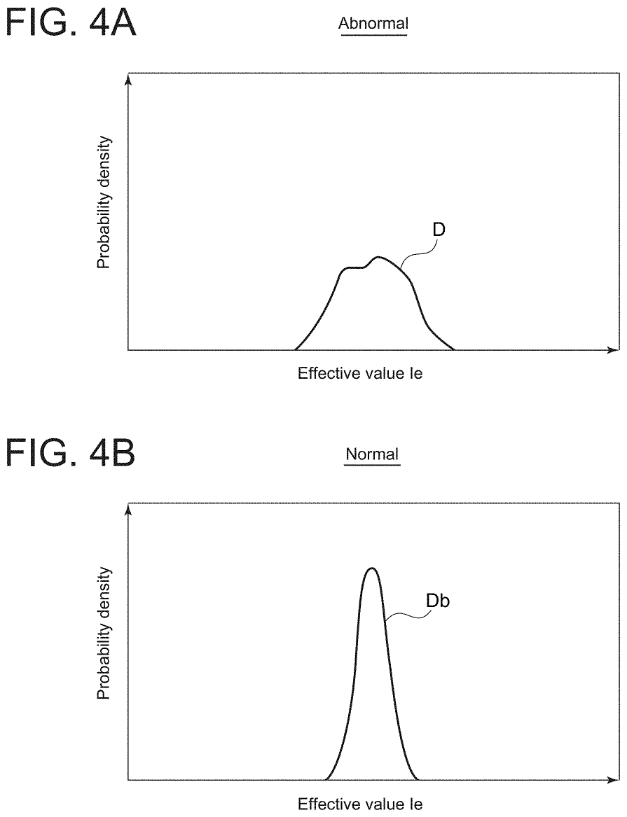

FIG. 3A is a diagram showing effective values of current for a certain type of abnormality in contrast between normal and abnormal conditions according to an embodiment of the present invention. FIG. 3B is a diagram showing effective values of current for another type of abnormality in contrast between normal and abnormal conditions according to an embodiment of the present invention. FIG. 4A is a diagram showing a probability density distribution of effective values Ie when the rotary machine is abnormal according to an embodiment of the present invention. FIG. 4B is a diagram showing a probability density distribution of effective values Ie when the rotary machine is normal according to an embodiment of the present invention. The scales of the vertical axis and the horizontal axis of FIGS. 3A and 3B are the same. Similarly, the scales of the vertical axis and the horizontal axis of FIGS. 4A and 4B are the same.

In some embodiments, as shown in FIG. 2, the diagnosis device 1 may further include a storage unit 5 configured to store normal distribution information Db which represents a distribution state of the effective value Ie for each specified number of cycles in a current waveform W (hereinafter, normal current waveform Wb) which is time transition of the measured current in a predetermined period (hereinafter, second predetermined period) when the diagnosis target machine 9 is in a normal state. Further, the detection unit 4 performs the abnormality detection on the basis of the target distribution information Dt and the normal distribution information Db. The number of effective values Ie acquired to generate the normal distribution information Db may be the same as that of the target distribution information Dt, or may be different, for example, may be 400 or more. Further, the number of samples of the instantaneous value of the current from the normal current waveform Wb may be the same as that of the target current waveform Wt, or may be different.

For example, as shown in FIGS. 3A and 3B, the plurality of effective values Ie varies in behavior between an abnormal state where an abnormality has occurred in the rotary machine 91 and a normal state where no abnormality has occurred. Specifically, as shown in FIGS. 3A and 3B, in the graph with the horizontal axis representing the number of one-cycle waveforms (the number of waveforms) of the instantaneous value of the current and the vertical axis representing the effective value Ie, when the effective values Ie are plotted for each of the abnormal state and the normal state, the amplitude of the effective values Ie in the abnormal state (abnormal) fluctuates more greatly than the amplitude of the effective values Ie in the normal state (normal). FIGS. 3A and 3B show the cases where the rotary machine 91 has different types of abnormalities.

Therefore, when the probability density distribution of the plurality of effective values Ie is calculated for both the abnormal state and the normal state of the diagnosis target machine 9, for example, FIGS. 4A and 4B are obtained. In the graphs of FIGS. 4A and 4B, the horizontal axis is the effective value Ie, and the vertical axis is the probability density. FIG. 4A shows the abnormal state, and FIG. 4B shows the normal state. The distribution is wider and the degree of variation is larger in the abnormal state than in the normal state. In other words, there is a difference in the distribution state of the effective values Ie between the normal state and the abnormal state, and thus the detection unit 4 performs abnormality detection on the basis of the difference in the distribution state between the target distribution information Dt and the normal distribution information Db.

The first predetermined period and the second predetermined period are periods that do not overlap each other, and the lengths of these periods are usually the same, but they may be different from each other. Further, the storage device 12 may store the normal current waveform Wb or the effective value Ie calculated on the basis of the unit current waveform Wu forming the normal current waveform Wb. In this case, the diagnosis device 1 may calculate the normal distribution information Db on the basis of the storage information of the storage device 12 and store it in the storage unit 5 before the abnormality detection by the detection unit 4. The storage unit 5 is formed in a predetermined storage area of the storage device 12 of the diagnosis device 1.

According to the above configuration, on the basis of comparison between the target distribution information Dt and the normal distribution information Db obtained from the current waveform W (normal current waveform Wb) of the diagnosis target machine 9 (rotary machine 91) in the normal state, the abnormality detection of the diagnosis target machine 9 is performed. Thereby, it is possible to appropriately determine whether the diagnosis target machine 9 (rotary machine 91) is normal or abnormal.

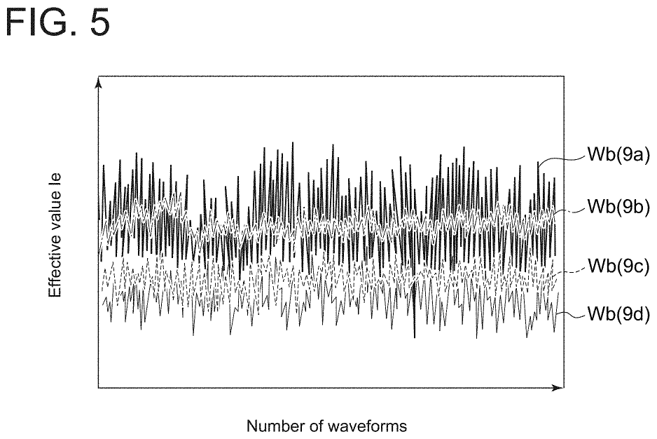

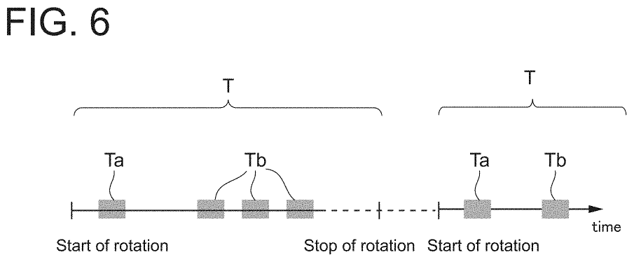

FIG. 5 is a diagram showing normal current waveforms Wb of a plurality of diagnosis target machines 9 in contrast to each other according to an embodiment of the present invention. FIG. 6 is a diagram for describing the flow of diagnosis according to an embodiment of the present invention.

In some embodiments, the normal distribution information Db may be prepared for each diagnosis target machine 9. The present inventors have found that, as shown in FIG. 5, even if the diagnosis target machines 9 are of the same type, the degree of magnitude of the amplitude of the normal current waveform Wb may not be the same, and the degree of change in the effective value Ie may not be the same among individuals.

In the graph of FIG. 5, the horizontal axis is the number of waveforms, and the vertical axis is the effective value Ie. When the normal current waveforms Wb of the plurality of (four in FIG. 5) diagnosis target machines 9 (9a to 9d), which are different individuals, are plotted on this graph, the changes in the amplitude of the effective value Ie differ as shown in FIG. 5. If the degree of changes in the amplitude of the effective value Ie differ, the normal distribution information Db may also differ. Therefore, by acquiring (storing) the normal distribution information Db for each diagnosis target machine 9 in advance through measurement or the like, and performing the abnormality detection on the basis of comparison between the target distribution information Dt and the normal distribution information Db of the diagnosis target machine 9 from which the target distribution information Dt has been acquired, it is possible to prevent erroneous detection.

In the embodiment shown in FIG. 2, the effective value acquisition unit 2 is configured to receive the measured value Im which is the effective value Ie or the instantaneous value of the measured current from the current measurement device 7 connected to the diagnosis target machine 9. Further, as shown in FIG. 6, the effective value acquisition unit 2 includes a first acquisition unit 21 configured to acquire the plurality of effective values Ie for the normal current waveform Wb, on the basis of the measured value Im input in a first operating period Ta set within a period T from the start of rotation to the stop of rotation of the rotary machine 91, and a second acquisition unit 22 configured to acquire the plurality of effective values Ie for the target current waveform Wt, on the basis of the measured value Im input in a second operating period Tb set after the first operating period Ta and before the stop of rotation of the rotary machine 91. Thus, the rotary machine 91 continues rotating between the first operating period Ta and the second operating period Tb.

In the embodiment shown in FIG. 6, after the rotary machine 91 starts to rotate and after the rotating state can be considered to be stable, the normality of the rotary machine 91 is checked, and then the first operating period Ta is set. Then, the second operating period Tb is periodically set, and the normality of the rotary machine 91 of the diagnosis target machine 9 is monitored. Similarly, after the rotation is stopped and the rotation is started again, the second operating period Tb is set after the first operating period Ta.

According to the above configuration, while the rotary machine 91 is continuously rotating without stopping, the measured value Im (instantaneous value of measured current or effective value Ie thereof) used for calculating the normal distribution information Db is acquired, and then the measured value Im used for calculating the target distribution information Dt is acquired. In other words, the state of the diagnosis target machine 9 during rotation of the rotary machine 91 before acquiring the target current waveform Wt is defined as normal, and the measured value Im obtained while the rotary machine is continuously rotating thereafter is monitored for diagnosis.

The present inventors have found that, depending on the type of abnormality in the rotary machine 91, the abnormality determination is more accurate when based on the distribution state of effective values Ie of the current than when based on the distribution state of instantaneous values of the current when the abnormality occurs (see Patent Document 2). Thus, even if the degree of variation of the plurality of effective values Ie obtained on the basis of the current waveform W varies among the individual diagnosis target machines 9 in the normal state, the normal state can be appropriately defined for each diagnosis target machine. Further, by periodically monitoring the change from the normal state while the rotary machine 91 is continuously rotating, it is possible to predict an abnormality based on the tendency.

Further, in the above-described embodiments, in some embodiments, the target distribution information Dt and the normal distribution information Db may be probability distributions such as probability density functions, and the detection unit 4 may perform abnormality detection on the basis of a distance between the target distribution information Dt and the normal distribution information Db which are probability distributions. This distance may be an index value capable of quantifying the difference between the two probability distributions (probability density functions), such as the well-known Kullback-Leibler distance and relative Pearson distance. When the probability distribution as the normal distribution information Db is expressed by p(x) and the probability distribution as the target distribution information Dt is expressed by p′(x), the relative Pearson distance can be calculated, for example, by ∫q_{α}(x)[{p(x)/qₐ(x)}−1]²dx, where q_{α}=αp+(1−α)p′ and 0≤α<1.

In the embodiment shown in FIG. 2, the detection unit 4 performs abnormality detection of the diagnosis target machine 9 on the basis of the relative Pearson distance between the probability distribution (e.g., probability density function) as the target distribution information Dt and the probability distribution as the normal distribution information Db. If the probability distribution of the effective values Ie is close to a normal distribution, the probability density is zero at the end of the probability distribution, but even in this case, the relative Pearson distance enables robust abnormality detection against noise.

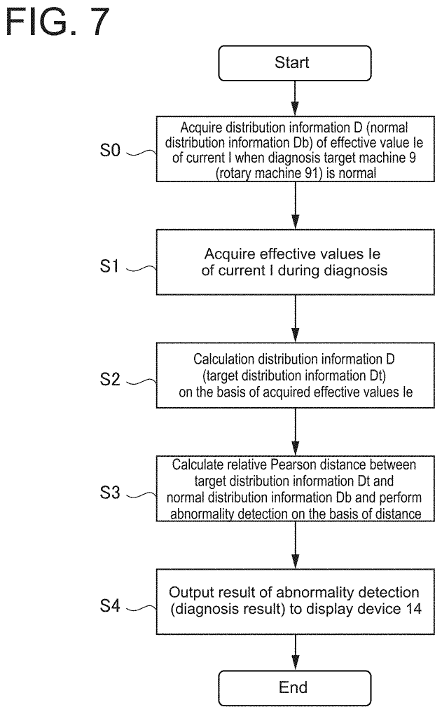

Hereinafter, the diagnosis method corresponding to the process performed by the diagnosis device 1 will be described with reference to FIG. 7. FIG. 7 is a diagram of the diagnosis method according to an embodiment of the present invention.

This diagnosis method is a method for diagnosing a diagnosis target machine 9 having a rotary machine 91 on the basis of a measured current during rotation of the rotary machine 91. As shown in FIG. 6, the diagnosis method includes an effective value acquisition step (S1), a distribution information calculation step (S2), and a detection step (S3). Each step will now be described.

Each step will be described in conjunction with the diagnosis system 6 shown in FIG. 1.

The effective value acquisition step (S1) is a step of acquiring an effective value Ie for each specified number of cycles in a target current waveform Wt. The effective value acquisition step (S1) is the same as the processing content performed by the effective value acquisition unit 2 as already described and thus not described again in detail.

The distribution information calculation step (S2) is a step of calculating target distribution information Dt of the plurality of effective values Ie acquired in the effective value acquisition step. The distribution information calculation step (S2) is the same as the processing content performed by the distribution information calculation unit 3 as already described and thus not described again in detail.

The detection step (S3) is a step of performing abnormality detection of the diagnosis target machine 9 on the basis of the target distribution information Dt calculated in the distribution information calculation step. The detection step (S3) is the same as the processing content performed by the detection unit 4 as already described and thus not described again in detail.

In the embodiment shown in FIG. 7, in step S0, the above-described normal distribution information Db is acquired. Specifically, the plurality of effective values Ie is acquired for the normal current waveform Wb on the basis of the measured value Im input in the first operating period Ta set within the period T from the start of rotation to the stop of rotation of the rotary machine 91 of the diagnosis target machine 9, and the normal distribution information Db is calculated on the basis of the plurality of effective values Ie thus acquired, and is stored in the storage unit 5. If the measured value Im is the effective value Ie of the current, the plurality of effective values Ie is obtained by inputting the measured values Im. In contrast, if the measured value Im is the instantaneous value of the measured current, the plurality of effective values Ie is calculated on the basis of the instantaneous values of the measured current during the second predetermined period as already described. The normal distribution information Db is acquired on the basis of the plurality of effective values Ie thus acquired.

Then, in step S1, the effective value acquisition step is performed to acquire a plurality of effective values Ie from the target current waveform Wt. In step S2, distribution information calculation step is performed to calculate target distribution information Dt. Then, in step S3, the detection step is performed to perform abnormality detection of the diagnosis target machine 9. In the embodiment shown in FIG. 6, a relative Pearson distance between the target distribution information Dt and the normal distribution information Db is calculated, and abnormality detection is performed on the basis of the relative Pearson distance. Further, in step S4, the result of abnormality detection is input to the output device 14, such as a display.

The present invention is not limited to the embodiments described above, but includes modifications to the embodiments described above, and embodiments composed of combinations of those embodiments.

### <Appendix>

(1) A diagnosis device (1) according to at least one embodiment of the present invention is a diagnosis device (1) for diagnosing a diagnosis target machine (9) having a rotary machine (91) on the basis of a measured current during rotation of the rotary machine (91) and comprises: an effective value acquisition unit (2) configured to acquire an effective value (Ie) of the measured current for each specified number of cycles in a target current waveform (Wt) which is time transition of the measured current in a first predetermined period; a distribution information calculation unit (3) configured to calculate a target distribution information (Dt) which represents a distribution state of a plurality of the effective values (le) acquired; and a detection unit (4) configured to perform abnormality detection of the diagnosis target machine (9) on the basis of the calculated target distribution information (Dt).

According to the above configuration (1), during rotation of the rotary machine (91) such as a turbine, a generator, or a motor of the diagnosis target machine (9), the effective value (le) of the current waveform (unit current waveform described below) for each specified number of cycles in the current waveform Wt, which is the time transition of instantaneous values of the current (measured current), such as alternating current supplied to the rotary machine (91) (e.g., electric motor) or alternating current output from the rotary machine (91) (e.g., generator), is acquired. Then, on the basis of information (target distribution information Dt) which represents the distribution state, such as probability density function and standard deviation, of the plurality of effective values (Ie) thus acquired, abnormality detection of the diagnosis target machine (9) is performed. Therefore, by executing the diagnosis of the rotary machine (91) on the basis of the distribution state (variation) of the plurality of effective values (Ie) of the current obtained from the target current waveform (Wt), it is possible to appropriately diagnose whether the rotary machine (91) is normal or abnormal.

(2) In some embodiments, in the above configuration (1), the diagnosis device further comprises a storage unit (5) configured to store normal distribution information (Db) which represents a distribution state of the effective value (le) for each specified number of cycles in a normal current waveform (Wb) which is time transition of the measured current in a second predetermined period when the diagnosis target machine (9) is in a normal state. The detection unit (4) performs the abnormality detection on the basis of the target distribution information (Dt) and the normal distribution information (Db).

According to the above configuration (2), on the basis of comparison between the target distribution information (Dt) and the normal distribution information (Db) obtained from the current waveform Wb of the diagnosis target machine (9) (rotary machine (91)) in the normal state, the abnormality detection of the diagnosis target machine (9) is performed. Thereby, it is possible to appropriately determine whether the diagnosis target machine (9) (rotary machine (91)) is normal or abnormal.

(3) In some embodiments, in the above configuration (2), the target distribution information (Dt) and the normal distribution information (Db) are probability distributions, and the detection unit (4) performs the abnormality detection on the basis of a distance between the target distribution information (Dt) and the normal distribution information (Db).

According to the above configuration (3), on the basis of the distance between the probability distribution (e.g., probability density function) as the target distribution information (Dt) and the probability distribution as the normal distribution information (Db), the abnormality detection of the diagnosis target machine (9) is performed. This makes it easy to detect an abnormality in the diagnosis target machine (9), for example, by determining normal or abnormal on the basis of comparison between the distance and a threshold.

(4) In some embodiments, in the above configuration (3), the distance is a relative Pearson distance.

According to the above configuration (4), on the basis of the relative Pearson distance between the probability distribution as the target distribution information (Dt) and the probability distribution as the normal distribution information (Db), the abnormality detection of the diagnosis target machine (9) is performed. If the probability distribution of the effective values (Ie) is close to a normal distribution, the probability density is zero at the end of the probability distribution, but even in this case, the relative Pearson distance enables robust abnormality detection against noise.

(5) In some embodiments, in the any one of the above configurations (2) to (4), the effective value acquisition unit (2) is configured to receive a measured value (Im) which is the effective value (Ie) or an instantaneous value of the measured current from a current measurement device (7) connected to the diagnosis target machine (9). The effective value acquisition unit includes (2): a first acquisition unit (21) configured to acquire the plurality of effective values (Ie) for the normal current waveform (Wb), on the basis of the measured value (Im) input in a first operating period (Ta) set within a period from start of rotation to stop of rotation of the rotary machine (91); and a second acquisition unit (22) configured to acquire the plurality of effective values (Ie) for the target current waveform (Wt), on the basis of the measured value (Im) input in a second operating period (Tb) set after the first operating period (Ta) and before the stop of the rotation.

According to the above configuration (5), while the rotary machine (91) is continuously rotating without stopping, the measured value (Im) (instantaneous value of measured current or effective value (Ie) thereof) used for calculating the normal distribution information (Db) is acquired, and then the measured value (Im) used for calculating the target distribution information (Dt) is acquired. In other words, the state of the diagnosis target machine (9) during rotation of the rotary machine (91) before acquiring the target current waveform (Wt) is defined as normal, and the measured value (Im) obtained while the rotary machine (91) is continuously rotating thereafter is monitored for diagnosis. Thus, even if the degree of variation of the plurality of effective values (Ie) obtained on the basis of the current waveform varies among the individual diagnosis target machines (9) in the normal state, the normal state can be appropriately defined for each diagnosis target machine (9). Further, by periodically monitoring the change from the normal state while the rotary machine (91) is continuously rotating, it is possible to predict an abnormality based on the tendency.

(6) In some embodiments, in the above configuration (5), the rotary machine (91) is in a continuously rotating state between the first operating period (Ta) and the second operating period (Tb).

With the above configuration (6), it is possible to achieve the same effect as the above configuration (5). Unless there is a change in conditions such as a change in the rotary machine (91), for example, as long as the rotary machine (91) is the same, the rotary machine (91) does not have to rotate continuously between the first operating period (Ta) and the second operating period (Tb).

(7) In some embodiments, in any one of the above configurations (1) to (6), the effective value (Ie) is calculated on the basis of a plurality of instantaneous values of the measured current obtained by sampling from the current waveform of the specified number of cycles. The number of samples by the sampling is from 900 to 1200 per cycle which constitutes the specified number of cycles.

According to the above configuration (7), since the number of samples is in the range of 900 to 1200, the target distribution information (Dt) that appropriately reflects the operating state (normal or abnormal) of the rotary machine (91) can be obtained, and diagnosis can be performed with appropriate diagnostic accuracy.

(8) In some embodiments, in any one of the above configurations (1) to (7), the specified number of cycles is one.

According to the above configuration (8), since the specified number of cycles is one, the target distribution information (Dt) that appropriately reflects the operating state (normal or abnormal) of the rotary machine (91) can be obtained, and diagnosis can be performed with appropriate diagnostic accuracy.

(9) In some embodiments, in any one of the above configurations (1) to (8), the distribution information calculation unit (3) calculates the target distribution information (Dt), on the basis of 400 or more effective values (Ie) acquired by the effective value acquisition unit (2).

According to the above configuration (9), by calculating the target distribution information (Dt) on the basis of 400 or more effective values (Ie), the operating state (normal or abnormal) of the rotary machine (91) can be appropriately reflected in the target distribution information (Dt).

(10) A diagnosis method according to at least one embodiment of the present invention is a diagnosis method for diagnosing a diagnosis target machine (9) having a rotary machine (91) on the basis of a measured current during rotation of the rotary machine (91) and comprises: a step (e.g., S1 of FIG. 6) of acquiring an effective value (Ie) of the measured current for each specified number of cycles in a target current waveform (Wt) which is time transition of the measured current in a first predetermined period; a step (e.g., S2 of FIG. 6) of calculating a target distribution information (Dt) which represents a distribution state of a plurality of the effective values (Ie) acquired; and a step (e.g., S3 of FIG. 6) of performing abnormality detection of the diagnosis target machine (9) on the basis of the calculated target distribution information (Dt).

With the above configuration (10), it is possible to achieve the same effect as the above configuration (1).

(11) A diagnosis program (10) according to at least one embodiment of the present invention is a diagnosis program (10) for diagnosing a diagnosis target machine (91) having a rotary machine (91) on the basis of a measured current during rotation of the rotary machine (91) and is configured to cause a computer to implement: an effective value acquisition unit (2) configured to acquire an effective value (Ie) of the measured current for each specified number of cycles in a target current waveform (Wt) which is time transition of the measured current in a first predetermined period; a distribution information calculation unit (3) configured to calculate a target distribution information (Dt) which represents a distribution state of a plurality of the effective values (Ie) acquired; and a detection unit (4) configured to perform abnormality detection of the diagnosis target machine (9) on the basis of the calculated target distribution information (Dt).

With the above configuration (11), the same effect is achieved as in the above (1).

### REFERENCE SIGNS LIST

1 Diagnosis device
10 Diagnosis program
11 Processor
12 Storage device
14 Output device
2 Effective value acquisition unit
21 First acquisition unit
22 Second acquisition unit
3 Distribution information calculation unit
4 Detection unit
5 Storage unit
6 6 Diagnosis system
7 Current measurement device
71 Communication medium
8 Electric panel
9 Diagnosis target machine
91 Rotary machine
I Current
Ie Effective value
Im Measured value
W Current waveform
Wb Normal current waveform
Wt Target current waveform
Wu Unit current waveform
Db Normal distribution information
Dt Target distribution information
T Period from start of rotation to stop of rotation of rotary machine
Ta First operating period
Tb Second operating period

1. A diagnosis device for diagnosing a diagnosis target machine having a rotary machine on the basis of a measured current during rotation of the rotary machine, the diagnosis device comprising:
an effective value acquisition unit configured to acquire an effective value of the measured current for each specified number of cycles in a target current waveform which is time transition of the measured current in a first predetermined period;
a distribution information calculation unit configured to calculate a target distribution information which represents a distribution state of a plurality of the effective values acquired; and
a detection unit configured to perform abnormality detection of the diagnosis target machine on the basis of the calculated target distribution information.

2. The diagnosis device according to claim 1, further comprising a storage unit configured to store normal distribution information which represents a distribution state of the effective value for each specified number of cycles in a normal current waveform which is time transition of the measured current in a second predetermined period when the diagnosis target machine is in a normal state,
wherein the detection unit performs the abnormality detection on the basis of the target distribution information and the normal distribution information.

3. The diagnosis device according to claim 2,
wherein the target distribution information and the normal distribution information are probability distributions, and
wherein the detection unit performs the abnormality detection on the basis of a distance between the target distribution information and the normal distribution information.

4. The diagnosis device according to claim 3,
wherein the distance is a relative Pearson distance.

5. The diagnosis device according to claim 2,
wherein the effective value acquisition unit is configured to receive a measured value which is the effective value or an instantaneous value of the measured current from a current measurement device connected to the diagnosis target machine, and
wherein the effective value acquisition unit includes:
a first acquisition unit configured to acquire the plurality of effective values for the normal current waveform, on the basis of the measured value input in a first operating period set within a period from start of rotation to stop of rotation of the rotary machine; and
a second acquisition unit configured to acquire the plurality of effective values for the target current waveform, on the basis of the measured value input in a second operating period set after the first operating period and before the stop of the rotation.

6. The diagnosis device according to claim 5,
wherein the rotary machine is in a continuously rotating state between the first operating period and the second operating period.

7. The diagnosis device according to claim 1,
wherein the effective value is calculated on the basis of a plurality of instantaneous values of the measured current obtained by sampling from the current waveform of the specified number of cycles, and
wherein the number of samples by the sampling is from 900 to 1200 per cycle which constitutes the specified number of cycles.

8. The diagnosis device according to claim 1,
wherein the specified number of cycles is one.

9. The diagnosis device according to claim 1,
wherein the distribution information calculation unit calculates the target distribution information, on the basis of 400 or more effective values acquired by the effective value acquisition unit.

10. A diagnosis method for diagnosing a diagnosis target machine having a rotary machine on the basis of a measured current during rotation of the rotary machine, the diagnosis method comprising:
a step of acquiring an effective value of the measured current for each specified number of cycles in a target current waveform which is time transition of the measured current in a first predetermined period;
a step of calculating a target distribution information which represents a distribution state of a plurality of the effective values acquired; and
a step of performing abnormality detection of the diagnosis target machine on the basis of the calculated target distribution information.

11. A diagnosis program for diagnosing a diagnosis target machine having a rotary machine on the basis of a measured current during rotation of the rotary machine, the diagnosis program being configured to cause a computer to implement:
an effective value acquisition unit configured to acquire an effective value of the measured current for each specified number of cycles in a target current waveform which is time transition of the measured current in a first predetermined period;
a distribution information calculation unit configured to calculate a target distribution information which represents a distribution state of a plurality of the effective values acquired; and
a detection unit configured to perform abnormality detection of the diagnosis target machine on the basis of the calculated target distribution information.
